(19) United States
(12) Patent Application Publication
(10) Pub. No.: US 2009/0275478 A1
(43) Pub. Date: Nov. 5, 2009

(54) METHOD AND APPARATUS FOR MAINTAINING A SUPERCONDUCTING SYSTEM AT A PREDETERMINED TEMPERATURE DURING TRANSIT

(76) Inventors: ANDREW FARQUHAR ATKINS, Steyning (GB); MARCEL JAN MARIE KRUIP, Oxford (GB); STEPHEN PAUL TROWELL, Louth (GB)

Correspondence Address: SCHIFF HARDIN, LLP;PATENT DEPARTMENT, 233 S. Wacker Drive-Suite 6600, CHICAGO, IL, 60606-6473, US

(21) Appl. No.: 12/432,859

(22) Filed: Apr. 30, 2009

(30) Foreign Application Priority Data
Apr. 30, 2008 (GB) 0807864.4

(51) Int. Cl. H01L 39/00; F25B 19/00

(52) U.S. Cl. 505/163; 62/51.1

(57) ABSTRACT

A superconductor system cooling apparatus, the apparatus comprising a casing, a solid coolant and a cooling circuit; wherein the cooling circuit comprises a heat exchanger, and a connector to couple the heat exchanger to a pre-cool loop of the superconductor system; wherein the cooling circuit further comprises a heat exchange medium to transfer heat between the solid coolant and the superconducting system.

### BACKGROUND OF THE INVENTION

1. Field of the Invention

This invention relates to cooling apparatus, in particular for use in superconductor systems, such as a cryostat of a magnetic resonance imaging (MRI) system.

2. Description of the Prior Art

Superconducting magnet systems are used for medical diagnosis, for example in magnetic resonance imaging systems. A requirement of an MRI magnet is that it produces a stable, homogeneous, magnetic field. In order to achieve the required stability, it is common to use a superconducting magnet system which operates at very low temperature. The temperature is typically maintained by cooling the superconductor by immersion in a low temperature cryogenic fluid, also known as a cryogen, such as liquid helium.

The superconducting magnet system typically has a set of superconductor windings for producing a magnetic field, the windings being immersed in a cryogenic fluid to keep the windings at a superconducting temperature, the superconductor windings and the cryogen being contained within a cryogen vessel. The cryogen vessel is typically surrounded by one or more thermal shields, and a vacuum jacket completely enclosing the shield(s) and the cryogen vessel.

An access neck typically passes through the vacuum jacket from the exterior, into the cryogen vessel. Such access neck is used for filling the cryogen vessel with cryogenic fluids and for passing services into the cryogen vessel to ensure correct operation of the magnet system.

Cryogenic fluids, and particularly helium, are expensive and it is desirable that the magnet system should be designed and operated in a manner to reduce to a minimum the amount of cryogen consumed. Heat leaks into the cryogen vessel will evaporate the cryogen which might then be lost from the magnet system as boil-off. The vacuum jacket reduces the amount of heat leaking to the cryogen vessel by conduction and convection. The thermal shields reduce the amount of heat leaking to the cryogen vessel by radiation, and by conduction if, as is the usual practice, the cryogen vessel supports and access neck are thermally linked to the shield so as to intercept heat being conducted along them. In order to further reduce the heat leaking to the cryogen vessel and thus the loss of liquid, it is common practice to use a refrigerator to cool the thermal shields to a low temperature. It is also known to use such a refrigerator to directly refrigerate the cryogen vessel, thereby reducing or eliminating the cryogen consumption. It is also known to use a two-stage refrigerator, in which a first stage is used to cool the thermal shield(s), and the second stage is used to cool the cryogen vessel.

It is desirable that such superconducting magnet systems should be transported from the manufacturing site to the operational site containing the cryogen, so that they can be made operational as quickly as possible. During transportation of an already assembled system, the refrigerator cooling the one or more shields and/or the cryogen vessel is inactive, and is incapable of diverting the heat load from the cryogen vessel. Indeed, the refrigerator itself provides a low thermal resistance path for ambient heat to reach the cryogen vessel and shield(s). This in turn means a relatively high level of heat input during transportation, leading to loss of cryogen liquid by boil-off to the atmosphere. It is desirable to reduce the loss of cryogen to the minimum possible, both since cryogens are costly and in order to prolong the time available for delivery, also known as the hold time, the time during which the system can remain with the refrigerator inoperable, but still contain some cryogen.

In prior configurations, the gas evaporated from the cryogen leaves the cryogen vessel solely through the access neck. It is well known that the cold gas from evaporating cryogenic fluids can be employed to reduce heat input to cryogen vessels, by using the cooling power of the gas to cool the access neck of the cryogen vessel and to provide cooling to thermal shields by heat exchange with the cold exhausting gas.

When the refrigerator of the superconductive magnet system is turned off for transportation, ambient heat is conducted along the passive refrigerator to reach the thermal shield(s) and/or the cryogen vessel. The refrigerator is typically removably connected to the thermal shield(s) and cryogen vessel by a refrigerator interface. It has been demonstrated that removing the refrigerator from the refrigerator interface can noticeably reduce the heat load onto the internal parts of the system, and therefore reduce the loss of cryogen.

However, further improvement is desired, both for cases where the refrigerator has been removed for transport and also in those cases where the refrigerator has not yet been installed. An advantage of transporting the system before installing the refrigerator is that the material typically used to make good thermal contact when the refrigerator is installed, Indium, although nominally making the refrigerator removable, can lead to problems with getting as good a thermal contact when the refrigerator is re-installed owing to parts of the original material remaining on the surfaces.

The processes required to achieve a thermal equilibrium include the necessity of cooling the thermal shield to a level of typically 30-50K. Under normal operating conditions the only source of cooling for the radiation shield is the first stage of the refrigerator. The refrigerator has a limited cooling capability and there can be long delays before the radiation shield is cold enough for the superconducting magnet to be energized. The problem during the cold transit of a superconducting magnet, is that no power is available to the shipping container, so the only form of cooling of such a system is enthalpy of the liquid Helium. The thermal shield is typically poorly coupled to this source of cooling and so the temperature of the radiation shield increases during the magnet transportation, increasing the thermal load on the Helium vessel due to radiation.

As is well known in the art, a difficulty arises when first cooling such a cryostat from ambient temperature. One option is to simply add working cryogen to the cryogen vessel until the cryogen vessel and the magnet settle at the temperature of the working cryogen. While this may be acceptable when using an inexpensive, non-polluting, essentially inexhaustible cryogen such as liquid nitrogen, it is not considered acceptable to use this approach for a working cryogen such as helium, which is relatively costly to produce, or to re-liquefy, and is a finite resource.

When cooling cryostats from ambient temperature to helium temperature, it is known to pre-cool the cryostat to a first cryogenic temperature by other means, before finally cooling the cryostat to operating temperature by the addition of liquid helium. One conventional method for pre-cooling the cryogen vessel to a first cryogenic temperature involves first adding an inexpensive sacrificial cryogen, typically liquid nitrogen, into the cryogen vessel. The cryostat is then left for some time for temperatures to settle. This may be known as ‘soaking’. The temperature of the cryogen vessel is then allowed to rise above the boiling point of the sacrificial cryogen, to ensure that it is completely removed from the cryogen vessel, before working cryogen is added. Although the material of the cryogen vessel itself quickly cools on addition of a cryogen, an issue arises with the cooling of the thermal radiation shield(s). In use, these thermal radiation shields must be cooled, typically to about 50K in the case of a single thermal radiation shield in a helium-cooled system. They must be thermally isolated from both the cryogen vessel and the OVC, to reduce the thermal influx from the room-temperature OVC to the cryogen vessel when in operating condition. When pre-cooling the cryostat, the thermal isolation of the thermal radiation shield(s) prevents the shield(s) from cooling rapidly on introduction of cryogen into the cryogen vessel. Known methods of pre-cooling a thermal radiation shield include: operating the refrigerator to cool the thermal radiation shields, or ‘softening’ the vacuum between the OVC and the cryogen vessel by the operation of an amount of gas, so allowing the thermal radiation shields to be cooled by convection heat transfer to the cryogen vessel. Each of these will now be discussed.

1) Operating the refrigerator to cool the thermal radiation shields has the disadvantage that any sacrificial cryogen within the cryogen vessel would need to be removed beforehand, since otherwise the sacrificial cryogen will be liquefied or frozen in the cryogen vessel. In known methods, the cryogen vessel is pre-cooled with nitrogen, allowed to warm up to a temperature in excess of the boiling point of nitrogen to ensure that no liquid nitrogen remains, and then is flushed with gaseous helium and then evacuated to ensure no contamination remains, before turning on the refrigerator. The refrigerator then cools the thermal radiation shield at a rate of about 1K/hr.

2) ‘Softening’ the vacuum between the OVC and the cryogen vessel will allow some thermal conductivity by convection, allowing heat to be transferred from the thermal radiation shield to the cryogen vessel, where it is removed by boiling of the sacrificial cryogen. Further cooling of the thermal radiation shield may occur by radiation once the working cryogen has been added into the cryogen vessel. Vacuum softening has been found to cool the thermal radiation shield rapidly to about 150 K when the cryogen vessel is filled with liquid nitrogen. Typically, the thermal radiation shield warms to 200 K during the phase when the cryogen vessel is allowed to warm to 80 K to ensure all liquid nitrogen is removed prior to filling with a liquid helium working cryogen. The refrigerator is then used to cool the thermal radiation shield from 200 K to 50 K. This process takes approximately 6 days, during which time approximately 200 liters of liquid helium are typically lost in boil off, at a significant cost.

While the financial cost of the lost helium is significant, the length of time required for cooling is also troublesome. Conventionally, the re-condensing operation of the refrigerator is tested before the cryostat is shipped to a customer. This requires cooling of the thermal radiation shield to about 50K, since higher thermal radiation shield temperatures will radiate more heat to the cryogen vessel than the re-condensing refrigerator can remove. However, more recently, the time taken to cool the thermal radiation shield has become the dominant factor in the time taken for magnet tests as a whole. This is particularly so in arrangements with a particularly low quench rate, which is otherwise most desirable. The pressure to ship completed cryostats and magnet systems to customers as soon has possible has led to the refrigerator re-condensing test being omitted from some testing protocols. This, in turn, can lead to difficulties later. For example, if any of these cryostats or magnet systems exhibit boil-off issues on, or after, installation, rapid problem diagnosis and correction will be hindered as their baseline cryogenic performance is unknown.

A particular problem after preparation and testing of the cryostat for dispatch to a customer site is the need to keep the system cool in transit, without an operational refrigerator.

### SUMMARY OF THE INVENTION

An object of the present invention is to provide a method and apparatus for maintaining a superconducting system at a predetermined temperature during transit of the superconducting system, without an operational refrigerator.

The above object is achieved in accordance with the present invention by a cooling apparatus for a superconducting system having a casing, a solid coolant, a cooling circuit that includes a heat exchanger and a pre-cooling loop of the superconducting system, and a connector that couples the heat exchanger to the pre-cooling loop. The cooling circuit also includes a heat exchange medium that transfers heat between the solid coolant and the superconducting system.

The above object is achieved in accordance with the present invention by a method for maintaining a superconducting system at a predetermined temperature during transit, that includes the steps of cooling a cryostat of the superconducting system to a predetermined temperature, installing a cooling apparatus as described above, operating the cooling apparatus during transit of the superconducting system to maintain the superconducting system substantially at the predetermined temperature during the transit thereof, and replenishing a source of the coolant in the cooling apparatus as necessary until installation of the superconducting system at the destination.

### BRIEF DESCRIPTION OF THE DRAWINGS

FIG. 1 is a block diagram of an example of a cooling apparatus according to the present invention;

FIG. 2 is a flow diagram illustrating an example of a method of operation of the cooling apparatus of FIG. 1.

### DESCRIPTION OF THE PREFERRED EMBODIMENTS

When transporting cryostats, they can either be shipped warm and cooled down on arrival, or kept cool during transport. Conventionally, nitrogen gas is not used on cargo ships because of the risk to the crew of suffocation, so when shipping by sea, helium gas as a coolant is preferred. For air transport, nitrogen gas is preferred. In the present invention, in transport, the refrigerator, or cold head, is removed from the cryostat and is replaced with a coolant pack of a solid cryogen, as for air transport in particular, active cryostats are not permitted. Solid nitrogen is a good choice in terms of being relatively low cost, being easy to obtain and having relatively high heat capacity. This allows cooling to be provided in a relatively compact package without the need for external power, which can be an issue when in transit. In the present invention, the solid nitrogen is used to keep the cryostat cool in transit, or to re-cool a cryostat when it arrives at its destination. Generally, the cryostat will still have some helium in it from its manufacturing tests, so that helium is allowed to boil off and later the cold pack acts to redress the heat influx through the refrigerator turret. A typical volume would be 80 liters of frozen nitrogen. The present invention can be used both for assisting in the cooling process, to bring the system down to a suitable temperature for testing or transport, as well as to hold the temperature down when no refrigerator can be used, e.g. in transit, so that the amount of cooling to be done on the customer site is minimized. If there is a facility on the customer site, then the invention may also be used to further cool the system toward operating temperature. An alternative method of cooling a magnet down on site would be to connect the magnet to an onsite mechanical cooling machine, such as a Stirling cooler. However, such coolers are bulky and require an infrastructure which provides sufficient mains power and cooling water.

Magnetic resonance imaging (MRI) magnets without liquid helium are typically delivered to a customer site at a temperature of 77 K. To cool the magnet down from the delivery temperature of 77 K to an operating temperature of 4 K takes between 139 liters of liquid helium at 100% efficiency and 2800 liters of liquid helium if only the latent heat of boil off is used. This can then require 1000 liters or more of liquid helium to be held on site, which is very costly. The present invention can be used to help to pre-cool the magnet to a temperature of less than 40 K which then will reduce the liquid helium requirement to less than 250 liters.

In a further embodiment, the present invention can provide all the cryogens required to compensate for the heat generation, particularly in the current leads, during the charging of the magnet with current, a process also known as ramping.

Generally, leaving the refrigerator running during transport is not possible for a number of practical, financial and regulatory reasons (e.g. International Maritime Dangerous Goods (IMDG) code or International Air Transport Association (IATA) regulations), so the refrigerator has to be removed for transport, or installed later. As illustrated in the subsequent examples, a solid coolant is provided and by means of a heat exchanger, the solid coolant cools a cryogen which is pumped around the cryostat, but no solid coolant enters the cryostat.

A suitable and preferred cryogen for keeping the magnet cold during transport is solid nitrogen, external to the magnet, because it can be removed on arrival at a relative low temperature and is comparatively inexpensive, although a range of alternative cryogens are available. These include frozen water, which has a penalty in terms of thermal capacity. However, solid water, hereafter called ice, offers practical advantages, in that it is a safe substance and a container filled with ice remains safe even if it warms up, but ice has a much smaller heat capacity, by about a factor of 5 compared to solid nitrogen

The apparatus remains connected to the magnet during the ramping process and provides cooling of the current leads, avoiding the requirement for liquid helium for this.

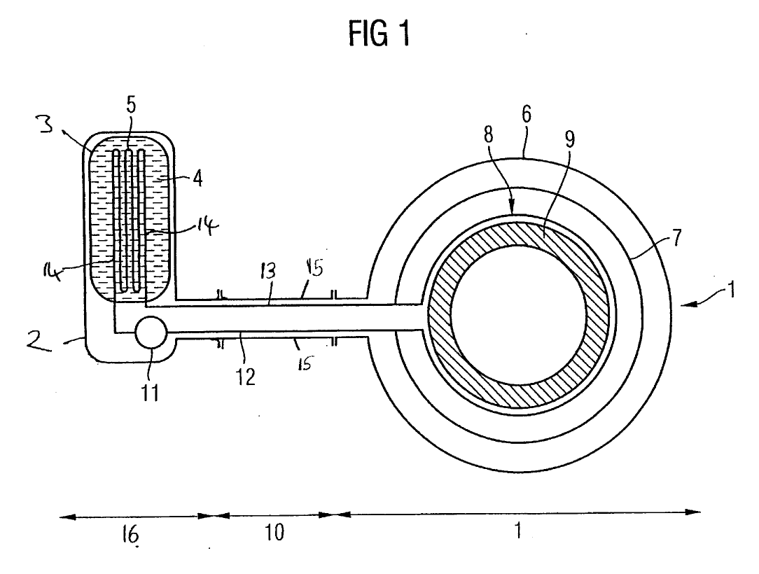

FIG. 1 illustrates an example of a cryostat 1 with a cooling apparatus according to the invention. The cooling apparatus comprises a cooling section 16 having an outer casing 2, a container 3, e.g. a stainless steel vacuum vessel, filled with solid coolant 4, typically a solid cryogen, or ice and a heat exchanger 5 fitted in the container within the quantity of coolant. The heat exchanger is preferably made of tubes 14 of copper, or similar high thermal conduction material, to improve heat transfer from a heat exchange medium (not shown) inside the tubes to the coolant 4, and has stainless steel connections to limit heat loss due to conduction. Multiple fins, internal and external, (not shown) may be added to the heat exchanger 5 to facilitate heat transfer.

The cryostat 1 being cooled has an outer vacuum chamber 6, a thermal shield 7 and a pre-cool loop 8 around a superconducting magnet 9. The pre-cool loop is typically made of a continuous tube of a high thermal conductivity material, such as copper, as for the heat exchanger. The heat exchange medium is constrained by the tube of the pre-cool loop and the medium in the pre-cool loop is independent of the pressure at which the cryostat operates, unlike convention pre-cool mechanisms, where the cryogen is in direct contact with the magnet. By using a tube of a high thermal conductivity material, heat can be transferred away from the magnet effectively via the contact between the tubes and the magnet, without the heat transfer medium itself coming into contact with the magnet. The magnet may also be immersed in cryogen at this stage, ready for operation, but does not have to be. The cooling section 16 of the cooling apparatus is connected to the cryostat 1 via a connection section 10, comprising input and output transfer lines 12, 13, which may also comprise metal tubes and the tubes 14 of the heat exchanger 5 are connected via these lines 12, 13 to the tube of the pre-cool loop 8 of the superconducting magnet 9 to form a cooling circuit. External to the tubes for the heat transfer medium, the outer casing 2, connector casing 15 and OVC 6 are also connected. A small vacuum pump (not shown) may be provided in the cooling apparatus in order to evacuate the cooling circuit 5, 8, 12, 13. This reduces heat losses during transport from a cooling station to a customer site.

The cooling apparatus may also be fitted with a store of pressurized gaseous helium (not shown) which allows the cooling circuit 5, 8, 12, 13 to be filled with gaseous helium, after the heat exchanger tubes 14 of the cooling section 16 has been connected to the tube of the pre-cool circuit 8 of the magnet 1. This gaseous helium is the transport medium which is used to transfer heat from the magnet 9 to the cooling apparatus 2. The cryogen used for the heat transfer means should be one that is wanted, not one which has to be cleaned out again, so an acceptable alternative cryogen is hydrogen. However, nitrogen could potentially poison the magnet, so is not used.

An impeller pump 11, or ‘fan’ may be fitted in the cooling circuit in order to provide the mass flow of the transfer medium. Generally, the fan is used only if it is desired to cool the magnet 9, as the fan adds energy to the system. The fan is positioned on an exhaust line 12 of the cooling apparatus and drives helium gas around the pre-cool loop 8. Unlike conventional pre-cool methods, there is no risk of nitrogen getting into the magnet, avoiding the need for the magnet to be cleaned out again. Alternatively, if there is no power for the pump, e.g. in transit, normal convection flow may be set up.

If the solid coolant in the cooling apparatus is nitrogen this gives better cryogenic effects, but using frozen water is a safe, cheap option for a coolant, with no problems when shipping, other than needing a larger quantity than if nitrogen is used. Nitrogen has two phase transitions, so makes a longer shipping time possible. With 100 liters of coolant in the magnet, the magnet could be kept cool until close to its destination, then the coolant removed and the refrigerator reinstalled. The solid coolant pack is typically suitcase sized for solid nitrogen and provided in a sealed vacuum jacket, e.g. stainless steel, filled with superinsulation, with a non-return valve to allow the nitrogen to escape. If frozen water is used as the coolant, then suitable measures must be taken to allow for the expansion of the ice when the water is frozen. An advantage of water is that, when freezing, it forms a good thermal/mechanical contact with the heat exchanger tubes.

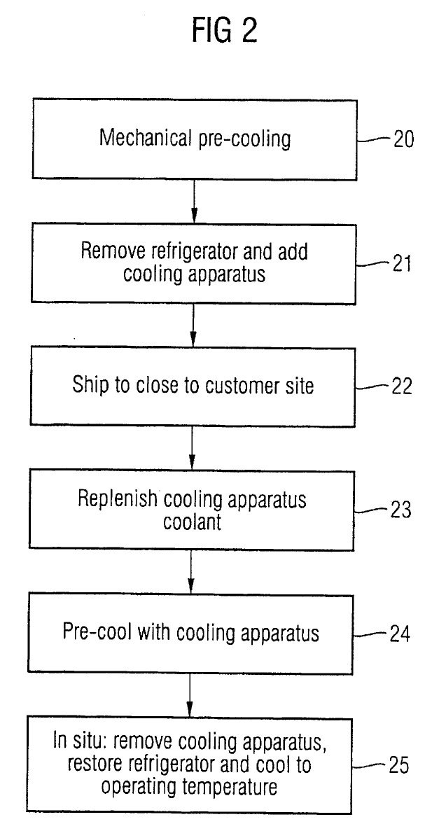

FIG. 2 illustrates an example of how the cooling apparatus of the present invention can be used. At the manufacturing site, most of the cooling can be done in an economical way with external mechanical refrigeration machines, so a cryostat is initially connected step 20 to a mechanical cooler to pre-cool the cryostat to around 77K. The pre-cool loop 8 of the magnet is connected 10 to the cooling section 16 once the liquid nitrogen has been removed.

The mechanical cooler is removed and the cooling apparatus connected up step 21 in preparation for transporting step 22 the cryostat to a customer site. When the cryostat is at or near to the customer site, the solid coolant is replenished step 23 and the cooling apparatus 8, 10, 16 used step 24 to pre-cool the cryostat. Typically, the cryogen in the cryostat is cooled to a temperature of 20K or less with an external cooler, which does not have to be on the customer site, but should be relatively nearby, such that the cryogen does not absorb significant amounts of heat during transport from its cool-down station to the customer's site. If done near to the customer site, the cooling apparatus remains in place to keep the cryostat cool for the last section of the journey. Once the cryostat is in situ, the cooling apparatus is removed 25, the refrigerator connected and the cryostat is cooled to operating temperature. That part of the cooling apparatus comprising a source of heat capacity in the form of a solid cryogen, a heat exchanger, and a transfer line to the magnet system is able to be returned to the manufacturing site and re-used on another magnet, reducing the costs of each shipment. In summary, the method of the invention comprises cooling a cryostat to a predetermined temperature, installing cooling apparatus to substantially maintain the temperature during transit, replenishing a source of cooling in the cooling apparatus as necessary until installation at a destination and optionally, using the cooling apparatus to pre-cool the superconductor system.

The invention provides an external source of cooling which not only keeps the magnet cool in transit, but has the benefit of a high peak power, so can also be used to reduce the temperature of the magnet at arrival on site after shipment, thereby reducing the requirement for costly liquid helium. The invention also allows for automation of the cool-down process, as well as maintaining the temperature during transport.

A specific example of the typical temperatures and heat loads involved is given below. For the example of a magnet with 700 kg of Cu and 444 kg of Aluminium, arriving on site with a customer at a temperature of 77 K and using the cooling apparatus having a quantity of 300 kg of solid nitrogen at a temperature of 20 K, then assuming a perfect heat exchange without ingress of heat, the magnet is cooled down to 38 K. From this temperature it takes a minimum of 241 liters of liquid helium to cool the magnet down if only the latent heat of boiling is used, or a minimum of 23 liters of liquid helium if all the enthalpy is used. The solid nitrogen of the cooling apparatus reduces the shield temperature and usually, there is about 200 mW thermal load through refrigerator when the system is not in use, but the refrigerator has been removed for transport. The thermal shield usually heats to about 200K, so thermal radiation to the magnet must be avoided. Convection in the helium slows heat input. When the refrigerator is operating it cools at 300 mW. When the refrigerator is off, then heat input is typically 1.3 W, i.e. 1 W at 4.2K plus 0.3 W of self cooling.

If transport delay causes the system to heat to greater than nitrogen temperature, then conventional cooling steps must be taken at significant financial cost.

Another application, as well as in transport of MRI magnets is for cooling of high temperature superconductor electric drive electric motors, or generators. In this case, active refrigeration may be provided, but to protect against a situation in which this refrigeration fails or must be temporarily stopped, then the solid coolant allows for the cooling of the superconducting electric motors or generators to be preserved for a period of time.

Although modifications and changes may be suggested by those skilled in the art, it is the intention of the inventors to embody within the patent warranted hereon all changes and modifications as reasonably and properly come within the scope of their contribution to the art.

We claim as our invention:

1. A superconductor system cooling apparatus, comprising
a casing;
a solid coolant;
a cooling circuit comprising a heat exchanger and a pre-cooling loop of the superconductor system;
a connector that couples the heat exchanger to the pre-cooling loop; and
a heat exchange medium that transfers heat between the solid coolant and the superconducting system.

2. An apparatus as claimed in claim 1, wherein the coolant comprises solid nitrogen or solid water.

3. An apparatus as claimed in claim 1, wherein the heat exchanger comprises a plurality of tubes of high thermal conductivity embedded in the solid coolant.

4. An apparatus as claimed in claim 3, wherein the heat exchanger is provided with an impeller for pumping the heat exchange medium though the tubes.

5. An apparatus as claimed in claim 3, wherein convection flow is set up to transport the heat exchange medium through the tubes.

6. An apparatus as claimed in claim 1, wherein the heat exchange medium is a liquid or gaseous cryogen.

7. An apparatus as claimed in claim 6, wherein the cryogen comprises one of hydrogen or helium.

8. An apparatus as claimed in claim 1, wherein the cooling apparatus further comprises a store for storing a quantity of the heat exchange medium.

9. An apparatus as claimed in claim 1, wherein the high temperature superconductor system comprises one of a cryostat, an electric generator and an electric motor.

10. An apparatus as claimed in claim 1, wherein the cooling apparatus further comprises a vacuum pump to evacuate the cooling circuit.

11. An apparatus as claimed in claim 1, wherein the cooling circuit comprises a closed loop carrying a coolant medium through tubes of the heat exchanger, the pre-cool loop and the connector.

12. An apparatus as claimed in claim 1, wherein the cooling apparatus cools current leads of the cryostat during ramping up.

13. A method for maintaining a superconducting system at a predetermined temperature during transit of the superconducting system, comprising the steps of:
cooling a cryostat of a superconducting system to a predetermined temperature;
installing a cooling apparatus at the superconducting system that includes a casing, a solid coolant, and a cooling circuit that includes a heat exchanger, a pre-cooling loop of the superconducting system and a connector that couples the heat exchanger to the pre-cooling loop, wherein the heat exchange medium transfers heat between the solid coolant and the superconducting system;
operating the cooling apparatus during transit of the superconducting system to maintain the superconducting system substantially at said predetermined temperature during said transit; and
replenishing a source of said coolant in the cooling apparatus as necessary until installation of the superconducting system at a destination.

14. A method as claimed in claim 13, wherein the cooling of the cryostat to a predetermined temperature uses a mechanical cooler.

15. A method as claimed in claim 13, the method further comprising, removing a refrigerator if installed.

16. A method as claimed in claim 13, wherein the installing comprises connecting the cooling apparatus to a pre-cooling loop of the cryostat.

17. A method as claimed in claim 13, wherein the method further comprises replenishing the solid coolant before cooling at the destination.

18. A method as claimed in claim 17, wherein the cooling comprises using the replenished cooling apparatus to pre-cool a magnet of the superconducting system to less than 40 K.

19. A method as claimed in claim 13, wherein the method further comprises, at the destination, replacing or installing the refrigerator and cooling to operating temperature.

20. A method as claimed in claim 19, wherein the method further comprises disconnecting the cooling apparatus before cooling to the operating temperature.

21. A method as claimed in claim 13, wherein the predetermined temperature is substantially 77K.

22. A method as claimed in claim 13, wherein the operating temperature is substantially 4K.
